(19) United States
(12) Patent Application Publication
(10) Pub. No.: US 2010/0163940 A1
(43) Pub. Date: Jul. 1, 2010

(54) IMAGE SENSOR AND METHOD FOR MANUFACTURING THE SAME

(76) Inventor: Hoon JANG, Chungbuk (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/645,552

(22) Filed: Dec. 23, 2009

(30) Foreign Application Priority Data
Dec. 31, 2008 (KR) 10-2008-0138818

(51) Int. Cl. H01L 27/146; H01L 31/18

(52) U.S. Cl. 257/292; 438/73; 438/98; 257/E27.133; 257/E31.113

(57) ABSTRACT

Provided are an image sensor and a method for manufacturing the same. The image sensor comprises a photodiode, a floating diffusion region, a reset transistor, and a drive transistor. The photodiode generates photocharges. The floating diffusion region accumulates the photocharges. The reset transistor has a source connected to the floating diffusion region, and has a gate and a drain connected to each other to perform a reset function. The drive transistor receives the photocharges and serves as a source follower buffer amplifier.

### CROSS-REFERENCE TO RELATED APPLICATION

This application claims the benefit under 35 U.S.C. §119 of Korean Patent Application No. 10-2008-0138818, filed Dec. 31, 2008, which is hereby incorporated by reference in its entirety.

### BACKGROUND

The present disclosure relates to an image sensor and a method for manufacturing the same.

Generally, image sensors are semiconductor devices that can convert optical images into electrical signals. Image sensors are roughly divided into charge coupled devices (CCDs) and complementary metal oxide semiconductor (CMOS) image sensors. In regard to CCDs, charge carriers are stored and transferred in individual metal-oxide-semiconductor (MOS) capacitors adjacent to each other. CMOS image sensors adopt a switching mode that forms MOS transistors as many as the number of pixels by a CMOS technology of using a control circuit and a signal processing circuit as peripheral circuits, and sequentially detects outputs using the MOS transistors.

CMOS image sensors convert information on a subject into electrical signals and generally include signal processing chips having photodiodes. An amplifier, an A/D converter, an internal voltage generator, a timing generator, and a digital logic are integrated into one chip, which has a considerable advantage of saving space, power, and cost.

The CMOS image sensor is classified into 3T type, 4T type, and 5T type according to the number of transistors in a unit pixel. For example, the 3T type CMOS image sensor includes one photodiode and three transistors, and the 4T type CMOS image sensor includes one photodiode and four transistors.

Components of pixels of less than about 1.75 ml are reduced or shared to secure a size of a light-receiving area. For this, two-shared pixel or four-shared pixel structures are used to increase the area of a photodiode. However, as the sharing structure also becomes complicated, there is a difficulty in a layout of metal interconnections and signal lines.

### BRIEF SUMMARY

Embodiments provide an image sensor that can reduce the number of transistors by sharing a portion of at least two unit pixels

Embodiments also provide an image sensor and a method for manufacturing the same, which can simplify a metal interconnection between a pixel and a transistor to enhance high optical characteristics.

Embodiments also provide an image sensor having a layout of the minimum area.

In one embodiment, an image sensor comprises: a photodiode generating photocharges; a floating diffusion region accumulating the photocharges; a reset transistor having a source connected to the floating diffusion region, and having a gate and a drain connected to each other to perform a reset function; and a drive transistor receiving the photocharges and serving as a source follower buffer amplifier.

In another embodiment, a method for manufacturing an image sensor having unit pixels comprises: forming a gate electrode of a reset transistor on a semiconductor substrate; forming a source region and a drain region at both sides of the gate electrode; forming a first insulating layer covering the gate electrode on the semiconductor substrate; forming a contact hole in the first insulating layer, the contact hole exposing both a portion of the gate electrode and a portion of the drain region; forming a contact electrode in the contact hole, the contact electrode electrically connecting the gate electrode and the drain region; and forming a metal interconnection connected to the contact electrode.

In still another embodiment, an image sensor comprises: first and second photodiodes disposed in a row on a semiconductor substrate; a floating diffusion region between the first and second photodiodes; a first transfer transistor between the first photodiode and the floating diffusion region; a second transfer transistor between the second photodiode and the floating diffusion region; a reset transistor connected to the floating diffusion region and having a gate electrode and a drain region connected to each other; and a drive transistor disposed in alignment with the reset transistor and connected to the floating diffusion region through a metal interconnection.

In yet another embodiment, a method for manufacturing an image sensor comprises: preparing a semiconductor substrate implanted with second conductive type impurities; forming a first device isolation layer at a portion of a first active region of the semiconductor substrate, and a second isolation layer having therein an isolated active region in a second active region; forming a reset transistor and first and second transfer transistors in the first active region, and forming a drive transistor in the second active region; and forming a first photodiode at one side of the first transfer transistor and a second photodiode at one side of the second transfer transistor by selectively implanting first conductive type impurities into the semiconductor substrate, the second photodiode being isolated from the first photodiode.

The details of one or more embodiments are set forth in the accompanying drawings and the description below. Other features will be apparent from the description and drawings, and from the claims.

### BRIEF DESCRIPTION OF THE DRAWINGS

FIG. 1 is a circuit diagram illustrating an image sensor.

FIG. 2 is a diagram illustrating an image sensor according to an embodiment.

FIGS. 3A and 3B are a circuit diagram illustrating a reset transistor of an image sensor, and a cross-sectional view of the reset transistor implemented in a device according to an embodiment.

FIG. 4 is a layout diagram illustrating a unit pixel in an image sensor according to an embodiment.

### DETAILED DESCRIPTION

Hereinafter, a CMOS image sensor according to embodiments will be described in detail with reference to the accompanying drawings.

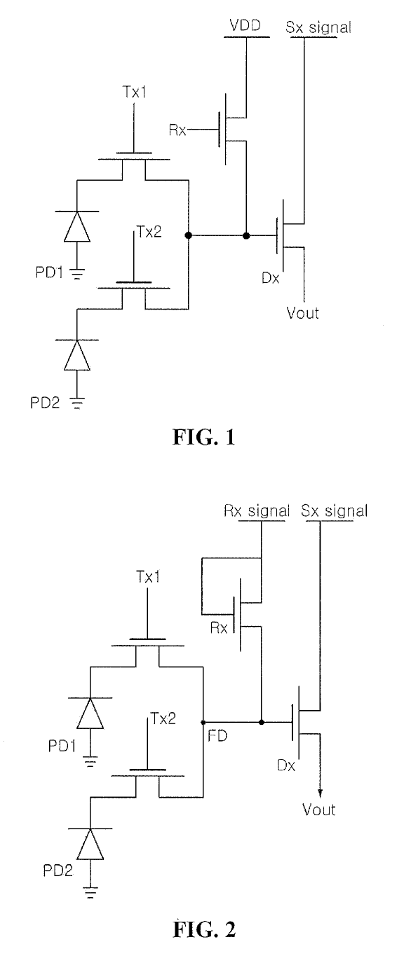

FIG. 1 is a circuit diagram illustrating an image sensor, and FIG. 2 is a diagram illustrating an image sensor according to an embodiment.

Referring to FIG. 1, a shared pixel of a CMOS image sensor includes a first photodiode PD1 and a second photodiode PD2 as a photoelectric conversion unit, a first transfer transistor Tx1 transmitting a signal delivered from the first photodiode PD1, a second transfer transistor Tx2 transmitting a signal delivered from the second photodiode PD2, a reset transistor Rx connected to the first and second transfer transistors Tx1 and Tx2 and used in common, and a drive transistor Dx.

The reset transistor Rx is connected between a floating diffusion region FD accumulating photocharges and VDD to perform a reset function.

If the power voltage VDD is supplied to the drain terminal of the reset transistor Rx, and a gate voltage of the reset transistor Rx is identical to the power voltage VDD, for example, 3V, then the reset transistor Rx is turned on to perform the reset function.

The drive transistor Dx receives photocharges from the floating diffusion region FD to serve as a source follower buffer amplifier. The drive transistor Dx receives a select signal for selecting a corresponding unit pixel. If the corresponding unit pixel is selected, the drive transistor Dx receives photocharges to amplify and output.

The shared pixel includes first and second photodiodes PD1 and PD2 adjacent in a column direction. The first and second photodiodes PD1 and PD2 absorb incident light, and accumulate charges corresponding to the intensity of radiation. Instead of the photodiodes, a phototransistor, a photogate, a pinned photodiode or a combination thereof may be applied.

Referring to FIG. 2, differently than the image sensor of FIG. 1, the gate and drain terminals of the reset transistor Rx are directly connected to each other. A reset signal RX signal of the reset transistor Rx, that is, VDD is simultaneously delivered to the gate terminal and the drain terminal. That is, when the reset function is performed, the reset signal, VDD is applied to the reset transistor Rx. When the reset function is not performed, the reset signal is not applied to maintain the reset transistor Rx turned off.

Accordingly, metal interconnections individually connected to the gate and drain terminals of the reset transistor may be reduced to one metal interconnection. The gate and drain terminals of the reset transistor may be short-circuited to be connected to the reset signal through the one metal interconnection.

The reset transistor Rx resets the floating diffusion region FD receiving charges accumulated in the photodiodes. The gate and drain terminals of the reset transistor Rx are simultaneously connected to a reset signal line applying a certain bias. If the reset signal, for example a power voltage VDD, is simultaneously delivered to the gate and drain terminals of the reset transistor Rx, then the reset transistor Rx is turned on, and the power voltage VDD is delivered to the floating diffusion region FD.

Here, the select transistor Sx is not separately provided. The select signal line is connected to a terminal of the drive transistor Dx, which serves to select a shared pixel of the line unit from a number of unit pixels.

If the shared pixel is selected by the select signal, the drive transistor Dx outputs a variation of an electrical potential of the floating diffusion region FD having received the charges accumulated in each photodiode to an output line.

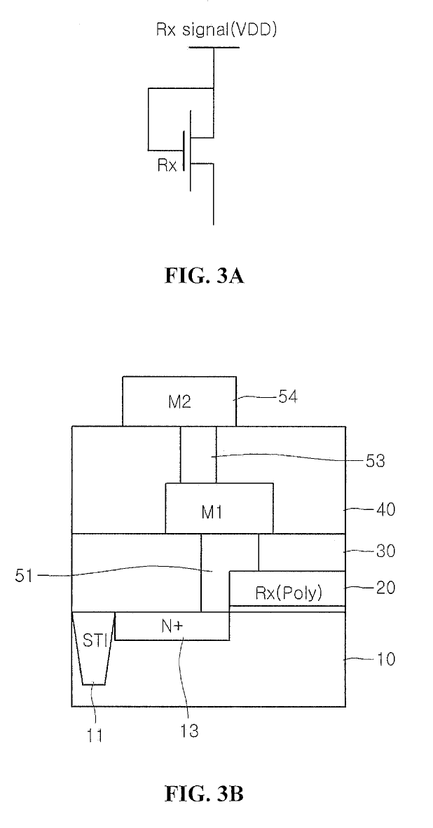

FIGS. 3A and 3B show a circuit diagram illustrating a reset transistor of an image sensor and a cross-sectional view of the reset transistor implemented in a device according to an embodiment. respectively.

Referring to FIG. 3A, the gate and drain terminals of the reset transistor Rx are simultaneously connected to the reset signal line applying a certain bias. If a reset signal, for example providing a power voltage VDD, is simultaneously delivered to the gate and drain terminals of the reset transistor Rx, then the reset transistor Rx is turned on, and the power voltage VDD is delivered to the floating diffusion region FD.

Referring to FIGS. 3A and 3B, a device isolation layer pattern 11 is formed on a semiconductor substrate 10. The device isolation layer pattern 11 may be a Shallow Trench Isolation (STI) that is formed by filling an insulating layer in a trench after the trench is formed to have a certain depth in the semiconductor substrate 10.

A gate electrode 20 is formed on a portion of an active region defined by the device isolation layer pattern 10. The gate electrode 20 may be formed of a polysilicon pattern.

Impurities may be selectively implanted to form a drain region 13 at one side of the gate electrode 20. Although not shown, a source region may be formed at the other side of the gate electrode 20. The source region may be connected to a floating diffusion region.

A first insulating layer 30 is formed over the semiconductor substrate 10 on which the gate electrode is formed. A contact hole is formed in the first insulating layer 30 to expose portions of the gate electrode 20 and the drain region 13 through the same contact hole. A portion of the upper surface and the side surface of the gate electrode may be exposed by the contact hole.

A contact electrode 51 is formed in the contact hole. The contact electrode 51 is formed of a metal such as tungsten, and is connected to both the gate electrode 20 and the drain region 13.

A first metal interconnection 52 connected to the contact electrode 51 is formed on the first insulating layer 30 in which the contact electrode 51 is formed.

A second insulating layer 40 is formed on the first metal interconnection 52. A via is formed to expose a portion of the first metal interconnection 52. A via metal 53 is formed in the via to contact the first metal interconnection 52.

Here, although only a second metal interconnection 54 is shown in FIG. 3B, the second metal interconnection 54 may be connected to a power line. A power voltage is simultaneously supplied to the gate electrode 20 and the drain region 13 of the reset transistor Rx through the power line, the second metal interconnection 54, the via metal 53, the first metal interconnection 52, and the contact electrode 51.

Thus, the signal line in a first metal layer (Ml) that is respectively connected to the gate electrode 20 and the drain region 13 of the reset transistor Rx can be removed, and the number of the metal interconnections and contact electrodes can be reduce to one by directly connecting the gate electrode 20 and the drain region 13 through a single contact hole.

This co-connection structure of the gate and drain terminals may be called a butting contact. That is, the size of the contact hole is formed greater and longer than the size of a contact hole of another part to short-circuit the gate and drain terminals.

Accordingly, the image sensor according to embodiments can share a portion of at least two unit pixels to reduce the number of transistors, and can simplify a configuration of metal interconnections connected to the transistors to enhance optical characteristics and reduce the manufacturing cost.

According to embodiments, a light receiving area of a photodiode can be considerably broadened by simplification of metal interconnections, thereby implementing a layout that can improve a fill factor.

According to embodiments, the image sensor can be advantageously integrated through a layout having a minimum area.

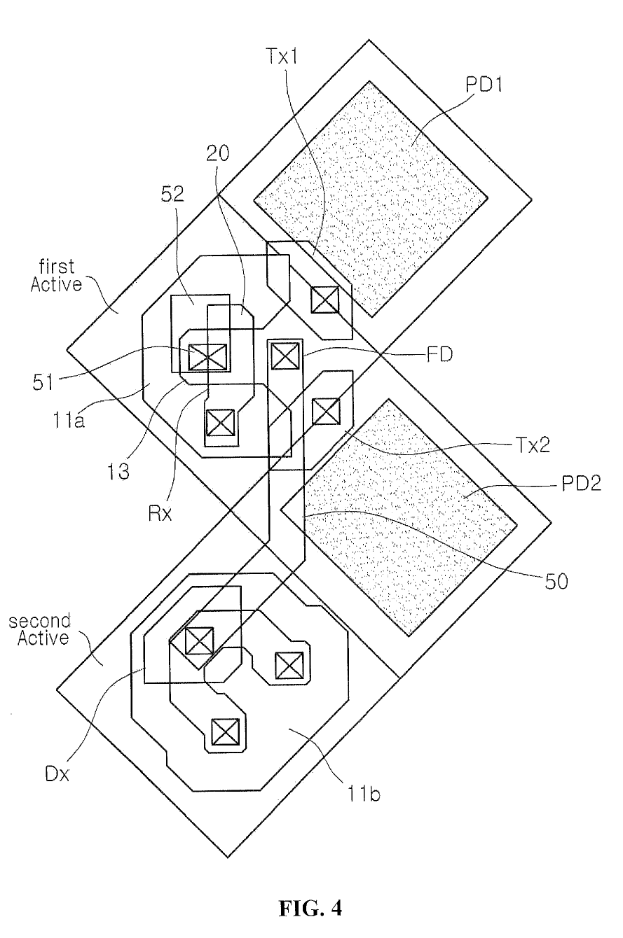

FIG. 4 is a layout diagram illustrating a unit pixel in an image sensor according to an embodiment.

Referring to FIG. 4, a unit pixel of an image sensor according to an embodiment has a shared pixel structure with two photodiodes, but may have four photodiodes and a structure sharing each circuit.

The shared pixel includes two adjacent photodiodes in a row direction. The first photodiode PD1 and the second photodiode PD2 have a diamond or polygonal shape.

The first and second photodiodes PD1 and PD2 are connected to a first transfer transistor Tx1 and a second transfer transistor Tx2, respectively.

The first and second transfer transistors Tx1 and Tx2 are formed between the first and second photodiodes PD1 and PD2. A floating diffusion region FD is formed between the first and second transfer transistors Tx1 and Tx2. The floating diffusion region FD is connected to the source region of the reset transistor Rx.

A first device isolation pattern 11a is formed to have a C-shape surrounding the drain region 13 of the reset transistor Rx. A gate electrode 20 is formed between the source region (at the floating diffusion region FD) and the drain region 13.

A contact electrode 51 is formed to be connected to both the gate electrode 20 and the drain region 13. The contact electrode 51 is connected to a first metal interconnection 52.

A drive transistor Dx is formed below (as viewed on the page) the reset transistor Rx in a row direction.

The drive transistor Dx has an active region having a C-shape isolated from another active region (second Active) by a second device isolation pattern 11b. The source region and the drain region are respectively formed at the ends of the C-shaped isolated active region of the drive transistor Dx. A gate electrode is formed between the source region and the drain region on the C-shaped isolated active region of the drive transistor Dx. The gate electrode is connected to the floating diffusion region through a first metal interconnection line 50.

As described above, the gate electrode 20 and the drain region 13 of the reset transistor Rx are directly connected to each other. A reset signal, such as a power voltage VDD, is simultaneously delivered to the gate electrode 20 and the drain region 13 through the contact electrode 51. That is, when a reset function is performed, the reset signal, i.e., the power voltage VDD, is applied to the reset transistor Rx. When the reset function is not performed, the reset signal is not applied to the reset transistor Rx, and the reset transistor Rx is turned off.

Accordingly, in an image sensor, metal interconnections individually connected to the gate and drain terminals of the reset transistor be reduced to one. The gate and drain terminals can be short-circuited to be connected to the reset signal.

According to an embodiment, in addition to a first device isolation pattern for defining the active region of the reset transistor Rx and a second device isolation pattern for defining the active region of the drive transistor Dx, the device isolation of the active region where the first and second photodiodes PD1 and PD2 are formed is performed through a junction.

That is, first conductive type impurities are ion-implanted into the first and second photodiodes PD1 and PD2, and second conductive type impurities are ion-implanted into the surroundings of the first and second photodiodes PD1 and PD2, thereby achieving device isolation.

Hereinafter, a layout of an image sensor according to an embodiment will be briefly described.

A reset transistor Rx, a first transfer transistor Tx1, and a second transfer transistor Tx2 are formed in a first active region (first Active).

A drive transistor Dx is formed in a second active region (second Active).

First and second photodiode regions PD1 and PD2 are disposed in a row. First and second active regions are disposed in a row. The first photodiode region PD1 and the second photodiode region PD2, and the first active region and the second active region are disposed in a zigzag pattern. That is, the first active region is disposed between the first photodiode region PD1 and the second photodiode region PD2.

The first and second transfer transistors Tx1 and Tx2 are symmetrically disposed in the first active region to connect to the first and second photodiode regions PD1 and PD2, respectively. A floating diffusion region FD is formed between the first and second transfer transistors Tx1 and Tx2. A reset transistor Rx is connected to the floating diffusion region FD. A first device isolation pattern 11a is formed to surround the drain region 13 of the reset transistor Rx in a C-shape. A contact electrode 51 is formed to be connected to both the gate electrode 20 and the drain region 13 of the reset transistor Rx.

The second active region is formed in the row direction at a position below the first active region. An active region of the drive transistor Dx is formed in a second device isolation pattern 11b formed in the second active region. The gate electrode of the drive transistor Dx is connected to the floating diffusion region FD through a first metal interconnection line 50.

Second conductive type impurities may be ion-implanted into boundaries of the first active region, the second active region, the first photodiode region PD1, and the second photodiode region PD2, thereby implementing implant isolation.

The first and second active regions and the first and second photodiode regions PD1 and PD2 may be formed to have a diamond shape, respectively.

Alternatively, the first and second active regions and the first and second photodiode regions PD1 and PD2 may each be formed to have another polygonal shape.

The image sensor according to embodiments has an effect of integration in that a unit pixel having a minimum area can be disposed by repeatedly arranging a layout of the unit pixel in a pixel region. Also, an area of a photodiode can be expanded to improve photosensitivity.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a photodiode generating photocharges;
a floating diffusion region accumulating the photocharges;
a reset transistor having a source connected to the floating diffusion region, and having a gate and a drain connected to each other to perform a reset function; and
a drive transistor receiving the photocharges and serving as a source follower buffer amplifier.

2. The image sensor according to claim 1, wherein the photodiode comprises a first photodiode and a second photodiode.

3. The image sensor according to claim 2, further comprising a first transfer transistor connected to the first photodiode and a second transfer transistor connected to the second photodiode,
wherein the first and second transfer transistors are connected to the floating diffusion region.

4. The image sensor according to claim 1, wherein the gate and drain of the reset transistor are connected through a single contact electrode that is connected to a power line to which a reset signal is applied.

5. The image sensor according to claim 1, wherein a reset signal applied to the connected gate and drain delivers a power voltage to the floating diffusion region.

6. A method for manufacturing an image sensor having unit pixels, the method comprising:
forming a gate electrode of a reset transistor on a semiconductor substrate;
forming a source region and a drain region at sides of the gate electrode;
forming a first insulating layer covering the gate electrode on the semiconductor substrate;
forming a contact hole in the first insulating layer, the contact hole exposing both a portion of the gate electrode and a portion of the drain region;
forming a contact electrode in the contact hole, the contact electrode electrically connecting the gate electrode and the drain region; and
forming a metal interconnection connected to the contact electrode.

7. The image sensor according to claim 6, further comprising forming a device isolation layer having a C-shape in the semiconductor substrate, the C-shape of the device isolation layer surrounding the drain region.

8. The image sensor according to claim 6, further comprising:
forming a first photodiode and a second photodiode in the semiconductor substrate; and
forming an implant isolation around the first and second photodiodes.

9. The image sensor according to claim 6, further comprising forming a power line on the first insulating layer and connected to the metal interconnection after the forming of the metal interconnection.

10. An image sensor comprising:
first and second photodiodes disposed in a row on a semiconductor substrate;
a floating diffusion region between the first and second photodiodes;
a first transfer transistor between the first photodiode and the floating diffusion region;
a second transfer transistor between the second photodiode and the floating diffusion region;
a reset transistor connected to the floating diffusion region and having a gate electrode and a drain region connected to each other; and
a drive transistor disposed in alignment with the reset transistor and connected to the floating diffusion region through a metal interconnection.

11. The image sensor according to claim 10, wherein an implant isolation is formed at a boundary between the first photodiode and the second photodiode in the semiconductor substrate.

12. The image sensor according to claim 10, further comprising a first device isolation layer having a C-shape formed in the semiconductor substrate, the C-shape of the first device isolation layer surrounding the drain region of the reset transistor.

13. The image sensor according to claim 10, wherein an active region of the drive transistor is formed in a C-shape, the active region being surrounded by a second device isolation layer.

14. The image sensor according to claim 10, wherein a first active region having the reset transistor and the first and second transfer transistors, a second active region having the drive transistor, and the first and second photodiodes each have a polygonal shape, wherein the first and second active regions and the first and second photodiodes are disposed in two lines and two rows.

15. A method for manufacturing an image sensor, comprising:
preparing a semiconductor substrate implanted with second conductive type impurities;
forming a first device isolation layer at a portion of a first active region of the semiconductor substrate, and a second isolation layer having therein an isolated active region in a second active region;
forming a reset transistor and first and second transfer transistors in the first active region, and forming a drive transistor in the second active region; and
forming a first photodiode at one side of the first transfer transistor and a second photodiode at one side of the second transfer transistor by selectively implanting first conductive type impurities into the semiconductor substrate, the second photodiode being isolated from the first photodiode.

16. The method according to claim 15, further comprising:
forming an insulating layer on an entire surface of the semiconductor substrate; and
forming a contact electrode in the insulating layer, the contact electrode being simultaneously connected to a gate and a drain of the reset transistor.

17. The method according to claim 16, further comprising forming a power line connected to the contact electrode.

18. The method according to claim 15, wherein the first and second photodiodes are isolated from each other by a region of second conductive type impurities implanted into the semiconductor substrate.
